(19) United States
(12) Patent Application Publication
(10) Pub. No.: US 2010/0252841 A1
(43) Pub. Date: Oct. 7, 2010

(54) OLED DEVICE HAVING IMPROVED LIFETIME AND RESOLUTION

(76) Inventors: Ronald S. Cok, Rochester, NY (US); Michael E. Miller, Honeoye Falls, NY (US)

Correspondence Address: MORGAN LEWIS & BOCKIUS LLP, 1111 PENNSYLVANIA AVENUE NW, WASHINGTON, DC, 20004, US

(21) Appl. No.: 11/532,569

(22) Filed: Sep. 18, 2006

(51) Int. Cl. H01L 51/52; H01L 51/56

(52) U.S. Cl. 257/89; 438/35; 257/E51.022

(57) ABSTRACT

An organic light-emitting diode device, includes a plurality of first patterned electrodes that define a corresponding plurality of light-emitting areas, and one-or-more organic first light-emitting layer(s) formed over the first patterned electrodes. A plurality of second patterned electrodes are formed over the one-or-more first light-emitting layer(s) corresponding to the first patterned electrodes; and one or more organic second light-emitting layer(s) formed over the second patterned electrodes. A third electrode common to the plurality of light-emitting areas is formed over the one-or-more second light-emitting layer(s). Each of the second patterned electrodes is shared between the first and second light-emitting layers so that the first and second patterned electrodes provide current through the first light-emitting layer(s); and each of the second and third electrodes, within each of the plurality of light-emitting areas, provide current through the second light-emitting layer(s) independent of the current through the first light-emitting layer.

### FIELD OF THE INVENTION

The present invention relates to organic light-emitting diode devices and, more particularly, to a patterned light-emitting device having stacked, independently controlled light-emitting elements.

### BACKGROUND OF THE INVENTION

Organic light-emitting diode (OLED) devices, also referred to as organic electroluminescent (EL) devices, have numerous well-known advantages over other flat-panel display devices currently in the market place. Among the potential advantages is brightness of light emission, relatively wide viewing angle, reduced device thickness, and reduced electrical power consumption compared to, for example, backlit displays.

Applications of OLED devices include active-matrix image displays, passive-matrix image displays, and area-lighting devices such as, for example, selective desktop lighting. Irrespective of the particular OLED device configuration tailored to these broad fields of applications, all OLEDs function on the same general principles. An organic electroluminescent (EL) medium structure is sandwiched between two electrodes. At least one of the electrodes is at least partially light transmissive. These electrodes are commonly referred to as an anode and a cathode in analogy to the terminals of a conventional diode. When an electrical potential is applied between the electrodes so that the anode is connected to the positive terminal of a voltage source and the cathode is connected to the negative terminal, the OLED is said to be forward biased. Positive charge carriers (holes) are injected from the anode into the EL medium structure, and negative charge carriers (electrons) are injected from the cathode. Such charge carrier injection causes current flow from the electrodes through the EL medium structure. Recombination of holes and electrons within a zone of the EL medium structure results in emission of light from this zone that is, appropriately, called the light-emitting zone or interface. The organic EL medium structure can be formed of a stack of sublayers that can include small molecule layers or polymer layers. Such organic layers and sublayers are well known and understood by those skilled in the OLED art.

Full-color OLED devices may employ a variety of organic materials to emit different colors of light. In this arrangement, the OLED device is patterned with different sets of organic materials, each set of organic materials associated with a particular color of light emitted. Each pixel in an active-matrix full-color OLED device typically employs each set of organic materials, for example to form a red, green, and blue sub-pixel. Patterning is typically done by evaporating layers of organic materials through a mask. In an alternative arrangement, a single set of organic materials emitting broadband light may be deposited in continuous layers with arrays of differently colored filters employed to create a full-color OLED device.

The emitted light is directed towards an observer, or towards an object to be illuminated, through the light transmissive electrode. If the light transmissive electrode is between the substrate and the light emissive elements of the OLED device, the device is called a bottom-emitting OLED device. Conversely, if the light transmissive electrode is not between the substrate and the light-emissive elements, the device is referred to as a top-emitting OLED device. The present invention may be directed to either a top-emitting or bottom-emitting OLED device. In top-emitting OLED devices, light is emitted through an upper electrode or top electrode, typically but not necessarily the cathode, which has to be sufficiently light transmissive, while the lower electrode(s) or bottom electrode(s), typically but not necessarily the anode, can be made of relatively thick and electrically conductive metal compositions which can be optically opaque. Because light is emitted through an electrode, it is important that the electrode through which light is emitted be sufficiently light transmissive to avoid absorbing the emitted light. Typical prior-art materials proposed for such electrodes include indium tin oxide (ITO) and very thin layers of metal, for example silver, aluminum, magnesium or metal alloys including these metals.

OLED devices age as current passes through the emissive materials of the display. Specifically, the emissive materials age in direct proportion to the current density passing through the materials. One approach to dealing with the aging problem, while maintaining the resolution of the display, is to stack two or more OLED light-emitting elements on top of each other thereby allowing the areas of the light-emitting elements to be larger to improve lifetime, and/or allowing more pixels to be provided for a given area, thereby improving resolution. This approach is described in U.S. Pat. No. 5,703,436 by Forrest et al., issued Dec. 30, 1997, and U.S. Pat. No. 6,274,980 by Burrows et al., issued Aug. 14, 2001. Stacked OLEDs utilize a stack of light emitting elements located one above another over a substrate. Each light-emitting element may share one or both electrodes with a neighboring light emitting element in the stack and each electrode is individually connected to an external power source, thereby enabling individual control of each light-emitting element. However, forming such structures is difficult and, especially, providing electrode connections may be problematic.

Referring to FIG. 5, a prior-art stacked OLED device is illustrated having a substrate 10 (either reflective, transparent, or opaque). Over the substrate 10, a first electrode 50 is formed. A first light-emitting layer 52 is formed over the first electrode 50 and a second electrode 54 formed over the first light-emitting layer 52. The first and second electrodes 50 and 54 provide current to the first light-emitting layer 52. An insulating layer 56 may be provided over the second electrode 54 to isolate it electrically from the third electrode 60 formed over the insulating layer 56. A second light-emitting layer 62 is formed over the third electrode 60 and a fourth electrode 64 formed over the second light-emitting layer 62. The third and fourth electrodes 60 and 64 provide current to the second light-emitting layer 62. An insulating layer 66 may be provided over the fourth electrode 64 to isolate it electrically from the fifth electrode 70 formed over the insulating layer 66. A third light-emitting layer 72 is formed over the fifth electrode 70 and a sixth electrode 74 formed over the third light-emitting layer 72. The fifth and sixth electrodes 70 and 74 provide current to the third light-emitting layer 72. Separate power connections 58, 68, 78 may be provided to independently control each of the first, second, and third light-emitting layers 52, 62, 72. The first, second, and third light-emitting layers 52, 62, 72 may emit three colors of light, for example red, green, and blue to form a full-color device.

U.S. Pat. No. 6,844,957, issued Jan. 18, 2005, entitled “Three Level Stacked Reflective Display”, by Matsumoto et al. describes a structure and fabrication technology for a reflective, ambient light, low-cost display incorporating a plurality of cells laid out side by side and stacked as many as three levels on top of each other. Each stack of three cells is being driven by an array of TFT's positioned on the bottom layer. Each cell comprises a light transmitting front window, three levels of individual cells RGB (Red, Green, and Blue) stacked on top of each other, each level having its own individual electrode, each electrode being connected by vertical conducting via holes running through each transparent dielectric spacer and being connected to an individual TFT. However, the formation of patterned electrodes and the spacing of vias may be difficult, particularly for devices employing organic layers since the use of masks and photolithographic techniques may damage organic material layers and are limited in resolution.

Alternative devices employing stacked light-emitting layers and color filters are also known. Commonly assigned, co-pending application, U.S. Ser. No. 11/087,522, filed Mar. 23, 2005 by Cok et al., entitled “OLED Display Device”, which is hereby incorporated in its entirety by reference, describes a full-color OLED display device comprised of a substrate; an array of light-emitting elements, each element comprised of a first EL unit positioned between and in electrical contact with a first pair of electrodes and a second EL unit positioned between and in electrical contact with a second pair of electrodes and located above or below the first EL unit, wherein the first EL unit emits light primarily in only two of the red, green and blue portions of the visible spectrum, and the second EL unit emits light at least in the remaining third portion of the visible spectrum; and a means for selectively filtering the light produced by the first EL unit to filter light from one of the only two of the red, green and blue portions of the visible spectrum in some light-emitting elements and to filter light from the other of the only two of the red, green and blue portions of the visible spectrum in some other light-emitting elements.

U.S. Pat. No. 6,903,378, issued Jun. 7, 2005, entitled “Stacked OLED Display Having Improved Efficiency” by Cok, which is hereby incorporated in its entirety by reference, describes an OLED device having a pixel, including a plurality of light transmissive filters; a first electrode layer defining a corresponding plurality of separately addressable electrodes; a first layer of white light emitting OLED material; a doped organic conductor layer; a second layer of white light emitting OLED material; and a second electrode layer defining a single electrode coextensive with the plurality of color filters. Similarly, US Publication No. 2005/0236981, filed Oct. 27, 2005, entitled “OLED Device” by Cok et al, which is hereby incorporated in its entirety by reference, describes an OLED device comprising a first layer of independently addressable light emitting elements; and a second layer of independently addressable light emitting elements located on top of the first layer; wherein one of the first and second layers of independently addressable light emitting elements comprises a patterned array of red and blue light emitting elements, and the other of the first and second layers of independently addressable light emitting elements comprises an array of green light emitting elements. However, neither of these disclosures describes a process for manufacturing the invention. In particular, the formation of a patterned electrode over a layer of organic materials is difficult.

It is known to provide shadowing insulative structures to pattern deposition. For example, U.S. Pat. No. 6,855,636, issued Feb. 15, 2005 to Theiss et al., entitled “Electrode Fabrication Methods For Organic Electro-Luminescent Devices” provides a process for selectively thermally transferring insulators onto organic electro-luminescent stacks or layers to electronically isolate adjacent devices upon deposition of electrode material. This can allow the formation of top electrodes for a plurality of organic electro-luminescent devices on a substrate via one deposition step to form a single common top electrode or a plurality of electrodes patterned by shadowing due to the presence of the insulators. U.S. Pat. Nos. 6,348,359, issued Feb. 19, 2002, entitled “Cathode Contact Structures in Organic Electroluminescent Devices” and 6,626,721, issued Sep. 30, 2003, entitled “Organic Electroluminescent Device with Supplemental Bus Cathode Conductor”, both to Van Slyke et al., describe passive matrix and active matrix organic electro-luminescent (EL) devices fabricated by using a single mask and employing electrically insulative organic shadowing structures. U.S. Pat. No. 6,727,645, issued Apr. 27, 2004, entitled “Organic LED Device”, by Tsujimura et al., also describes the use of shadowing structures. However, the structures described do not provide a means for improving the lifetime or resolution of OLED devices.

There is a need therefore for an improved organic light-emitting diode device structure that increases the resolution and improves lifetime.

### SUMMARY OF THE INVENTION

In accordance with one embodiment, the invention is directed towards an organic light-emitting diode device that includes a plurality of first patterned electrodes that define a corresponding plurality of light-emitting areas, and one-or-more organic first light-emitting layer(s) formed over the first patterned electrodes. A plurality of second patterned electrodes are formed over the one-or-more first light-emitting layer(s) corresponding to the first patterned electrodes; and one or more organic second light-emitting layer(s) formed over the second patterned electrodes. A third electrode common to the plurality of light-emitting areas is formed over the one-or-more second light-emitting layer(s). Each of the second patterned electrodes is shared between the first and second light-emitting layers, within each of the plurality of light-emitting areas, so that the first and second patterned electrodes provide current through the first light-emitting layer(s); and each of the second and third electrodes, within each of the plurality of light-emitting areas, provide current through the second light-emitting layer(s) independent of the current through the first light-emitting layer.

### ADVANTAGES

The present invention has the advantage that it increases the resolution and lifetime of light-emitting organic display devices.

### BRIEF DESCRIPTION OF THE DRAWINGS

FIG. 1 is a cross section of an OLED device having stacked emissive layers according to one embodiment of the present invention;

FIG. 2 is a cross section of an OLED device having stacked emissive layers and a color filter according to another embodiment of the present invention;

FIG. 3 is a flow diagram of a method of making the present invention;

FIGS. 4A-C are cross sections of an OLED device in various stages of construction according to the embodiment of FIG. 1 and the method of FIG. 3;

FIG. 5 is a cross section of a stacked OLED device according to the prior art; and

FIG. 6 is a photomicrograph of a shadowing pillar useful in various embodiments of the present invention;

FIG. 7 is a cross section of a stacked OLED device having a two-layer electrode according to an alternative embodiment of the present invention;

FIG. 8 is a cross section of a stacked OLED device having a plurality of light-emitting areas according to an embodiment of the present invention;

FIG. 9 is a circuit diagram of illustrating the electrical connections of a stacked OLED according to an embodiment of the present invention; and

FIG. 10 is a three-dimensional view of a substrate with pillars useful in various embodiments of the present invention.

It will be understood that the figures are not to scale since the individual layers are too thin and the thickness differences of various layers too great to permit depiction to scale.

### DETAILED DESCRIPTION OF THE INVENTION

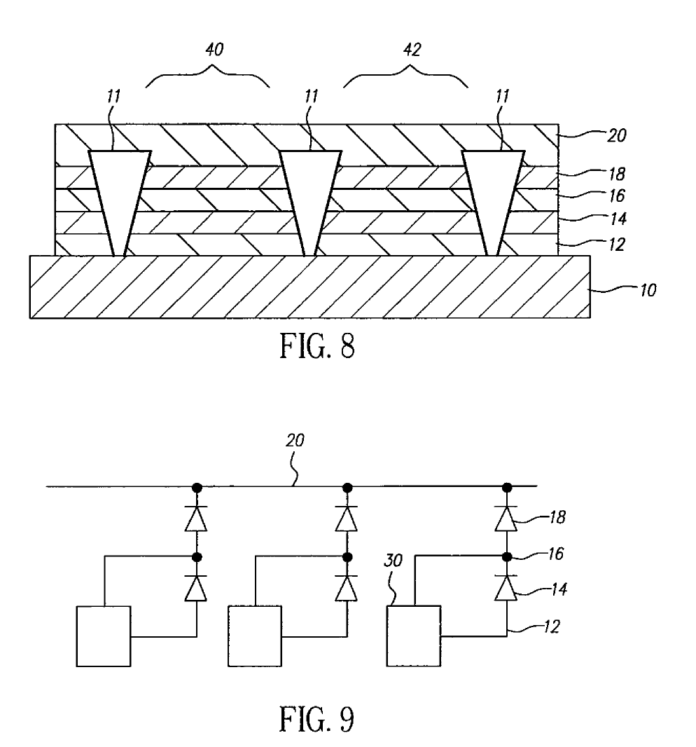

Referring to FIGS. 1 and 8, in accordance with one embodiment of the present invention, an organic light-emitting diode device comprises a plurality of first patterned electrodes 12 that define a corresponding plurality of light-emitting areas 40, 42, one-or-more organic first light-emitting layer(s) 14 formed over the first patterned electrodes 12, a plurality of second patterned electrodes 16 formed over the one-or-more first light-emitting layer(s) 14 corresponding to the first patterned electrodes 12, one or more organic second light-emitting layer(s) 18 formed over the second patterned electrodes 16, a third electrode 20 common to the plurality of light-emitting areas 40, 42, formed over the one-or-more second light-emitting layer(s) 18, wherein each of the second patterned electrodes 16 is shared between the first and second light-emitting layers 14 and 18 respectively, within each of the plurality of light-emitting areas 40, 42, so that the first and second patterned electrodes 12 and 16 respectively provide current through the first light-emitting layer(s) 14 and each of the second and third patterned electrodes 16 and 20 respectively, within each of the plurality of light-emitting areas 40, 42, provide current through the second light-emitting layer(s) 18 independent of the current through the first light-emitting layer 14.

The first patterned electrodes 12 define a light-emitting area (e.g. 40) by providing current to the first light-emitting layer 14. The second patterned electrodes 16 corresponds in location to the first patterned electrode 12 so that the light-emitting area formed by providing current to the second light-emitting layer 18 by electrodes 16 and 20 corresponds in location to the light emitted by the first light-emitting layer 14 even though third electrode 20 is common to the plurality of light-emitting areas (e.g. 40, 42). Note that the organic material layers 14 and 18 do not have to be patterned to produce distinct and separate light-emitting areas 40 and 42 since the first and second patterned electrodes 12 and 16 are patterned.

Second patterned electrode 16 is shared between the light-emitting layers 14 and 18. Hence, current flowing through the light-emitting layer(s) 14 passes through the second patterned electrode 16. Likewise, current flowing through the light-emitting layer(s) 18 passes through the second patterned electrode 16. However, because the first patterned electrode 12 and second patterned electrode 16 are independently controlled, the current passing through the light-emitting layer(s) 14 and the current flowing through the light-emitting layer(s) 18 may be independently controlled so that the amount of light emitted from the light-emitting layers 14 and 18 respectively may be independently controlled. Third electrode 20 may also be controlled but is electrically connected in common to all of the light-emitting areas (e.g. 40, 42) so that all light-emitting areas will have a common electrode voltage and/or current.

In one embodiment of the present invention, the OLED device may be a top-emitting device and the first patterned electrode 12 may be reflective while the second patterned electrode 16 and third electrode 20 are transparent. In another embodiment of the present invention, the OLED device may be a bottom-emitting device and the third electrode 20 may be reflective while the first patterned electrode 12 and the second patterned electrode 16 are transparent.

The patterned electrodes 12 and 16 together form distinct and separate light-emitting areas (e.g. 40, 42) over the surface of the substrate 10, for example sub-pixel elements in a display device. The separate light-emitting areas 40, 42, may be driven by the thin-film electronic circuit 30 as shown in FIG. 1 in an active-matrix configuration. In an alternative embodiment of the present invention, the electrodes 12, 16, 20 are connected to busses and controlled in a passive-matrix configuration (not shown).

According to various embodiments of the present invention, the first and second one-or-more light-emitting layers 14 and 18 may be independently controllable to emit light separately or together. Moreover, the light-emitting layers may each comprise a common light-emitting material layer over all of the light-emitting areas. Alternatively, the light-emitting materials comprising the light-emitting layers may be patterned so that one light-emitting layer in one light-emitting area will employ one kind of light-emitting material to emit light of one color while a different kind of light-emitting material may be employed in a different light-emitting area to emit light of a different color. Typically, in the prior art, organic materials are evaporated in layers over a substrate to form light-emitting layer(s). If no masking is employed, all of the light-emitting areas over the substrate have the same organic materials and will emit the same color of light in response to a current. If a precision shadow mask is employed, different light-emitting materials may be applied to different light-emitting areas. According to alternative embodiments of the present invention, either the first or second light-emitting layer(s) may be patterned with different light-emitting materials that can emit different colors of light in different light-emitting areas or either the first or second light-emitting layer(s) may employ the same light-emitting materials and emit the same color of light in different light-emitting areas.

In a particular embodiment of the present invention, the patterned electrodes may form a plurality of distinct and separate light-emitting areas, and the first light-emitting layer(s) may emit the same first color of light in each of the plurality of light-emitting areas and the second light-emitting layer(s) may emit the same second color of light in each of the plurality of light-emitting areas and wherein the first and second colors are different colors. A variety of different first and second color combinations may be employed. In some useful embodiments, complementary colors can be employed together to form a white light when both the first and second light-emitting layers are energized simultaneously. For example, one of the first or second light-emitting layer(s) may emit green light and the other of the first or second light-emitting layers may emit magenta light; or one of the first or second light-emitting layer(s) may emit blue light and the other of the first or second light-emitting layers may emit yellow light; or one of the first or second light-emitting layer(s) may emit red light and the other of the first or second light-emitting layers may emit cyan light. In another example, the two layers may each emit a secondary color of light. That is, the two layers be formed to emit any two colors of light from the list including cyan, yellow, and magenta.

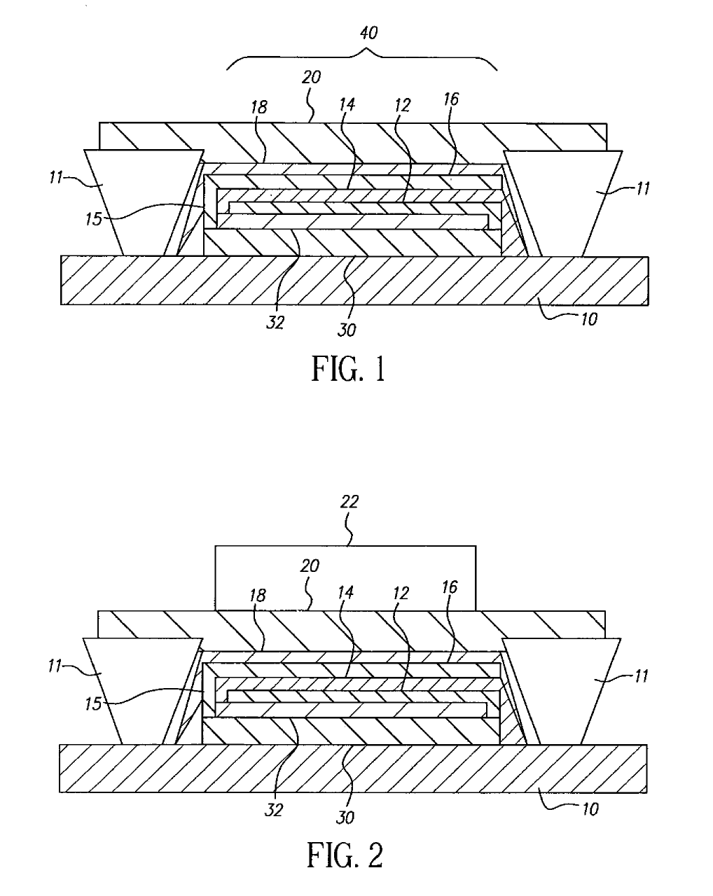

This embodiment may be particularly useful in combination with color filters, as shown in FIG. 2. Different color filters may be employed in different light-emitting areas. Referring to FIG. 2, a color filter 22 is employed in a top-emitter configuration to filter the light output by the first and second light-emitting layers 14 and 18. Such an arrangement is useful to provide a full-color device without the need to pattern (for example with a shadow-mask) the light-emitting layers 14 and 18. According to various disclosures in the prior art, a single, white-light-emitting layer in combination with patterned red, green, and blue color filters can form a full-color device. However, such a prior-art arrangement is inefficient because only approximately one third of the white light will pass through each of the color filters. In contrast, the present invention provides an improved energy efficiency by employing complementary colored emitters (e.g. green and magenta) together with patterned color filters that transmit two colors of light rather than one (e.g. yellow). In this example, if the green light-emitting layer is energized to produce green light, it may pass through the yellow filter with little absorption. If the magenta light-emitting layer is energized to produce magenta light, it may pass through the yellow filter to produce red while the blue component of the magenta light will be absorbed. If a cyan filter is employed, the blue component of the magenta light may pass through while the red component of the magenta light is absorbed. In this embodiment, only one third of the light is absorbed at each light-emitting area, rather than the two thirds of the prior-art example. Hence, a full-color device may be obtained using unpatterned light-emitting layers and a patterned color filter array having two colors that has a higher efficiency than the conventional white emitter with red, green, and blue color filters. Similarly, blue and yellow emitters may be employed with cyan and magenta filters; red and cyan emitters may be employed with yellow and magenta filters. In the case where the two layers each emit a secondary color of light cyan and yellow emitters may be employed with magenta and green filters, cyan and magenta emitters may be employed with blue and yellow filters, and yellow and magenta emitters may be employed with red and cyan filters.

In an alternative embodiment of the present invention, the patterned electrodes may form a plurality of distinct and separate light-emitting areas, and one of the first and second light-emitting layer(s) may emit light of different colors in different light-emitting areas and the other of the first and second light-emitting layer(s) may emit light of the same color in all light-emitting areas. For example, the patterned light-emissive layer(s) may be patterned to emit red and blue light in different light-emitting areas while the unpatterned light-emissive layer may emit green light. In this case, the resolution of the device is increased.

In yet another embodiment of the present invention, the patterned electrodes may form a plurality of distinct and separate light-emitting areas and both of the first and second light-emitting layer(s) may emit light of different colors in different light-emitting areas.

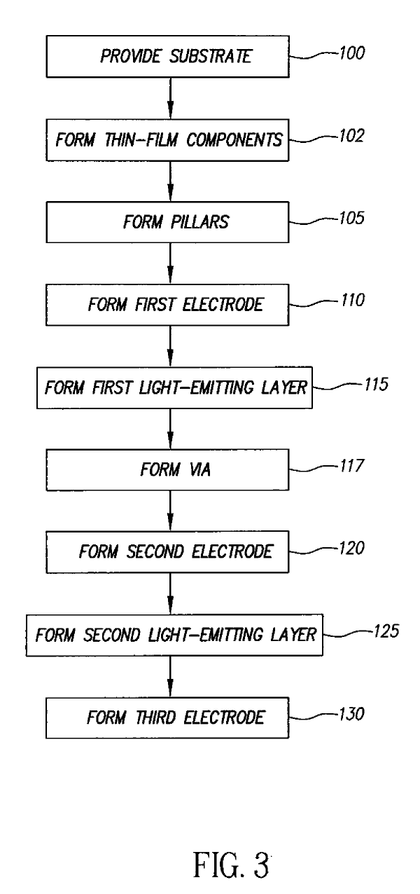

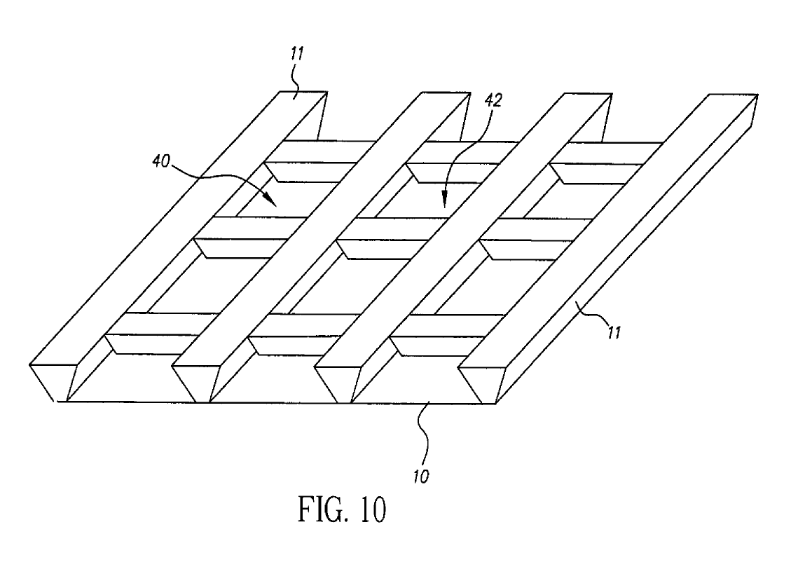

Referring to FIGS. 3 and 10, according to one method of the present invention, the device may be constructed by the steps of providing a substrate 100, forming 105 electrically insulating shadowing pillars 11 on the substrate 10, forming 110 first patterned electrodes on the substrate, forming 115 one-or-more organic or inorganic first light-emitting layer(s) over the first patterned electrode, forming 120 a second patterned electrode over the one-or-more first light-emitting layer(s), forming 125 one-or-more organic or inorganic second light-emitting layer(s) over the second patterned electrode; and forming 130 a third common electrode over the one-or-more second light-emitting layer(s).

In a further embodiment of a method of the present invention, thin-film electronic components may be formed 102, wherein the first patterned electrodes 12 are electrically connected to the thin-film electronic components 30, and forming 117 a via through the one-or-more first light-emitting layer(s) 14 to electrically connect the second patterned electrode 16 to the thin-film electronic components 30 when the second patterned electrode 16 is formed. The via may be formed by laser ablation of the first light-emitting layer(s) 14.

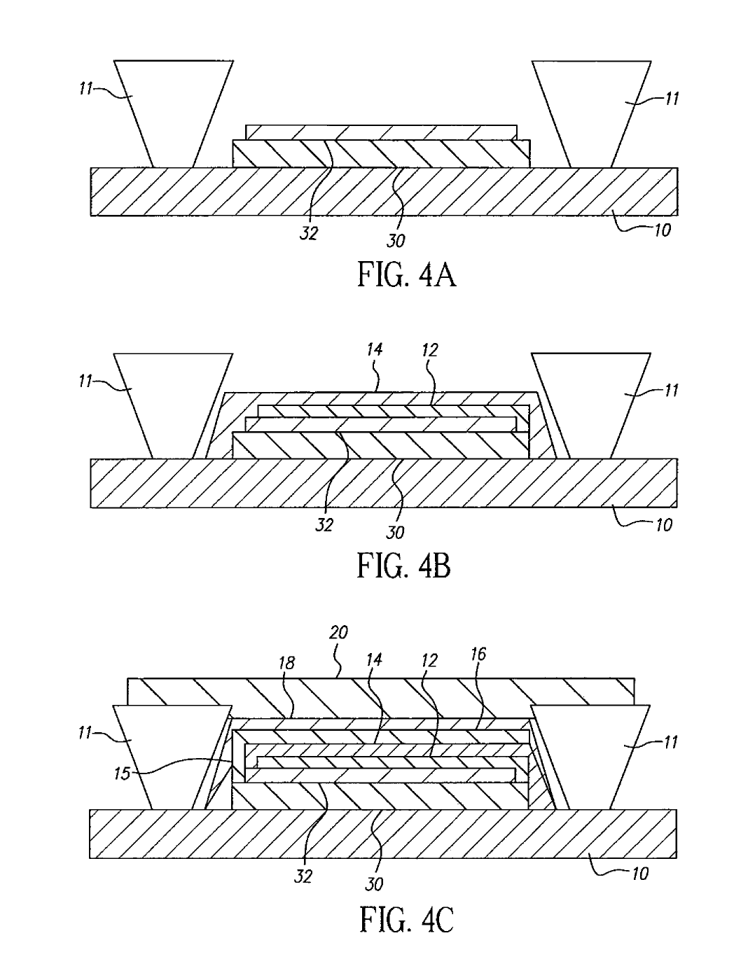

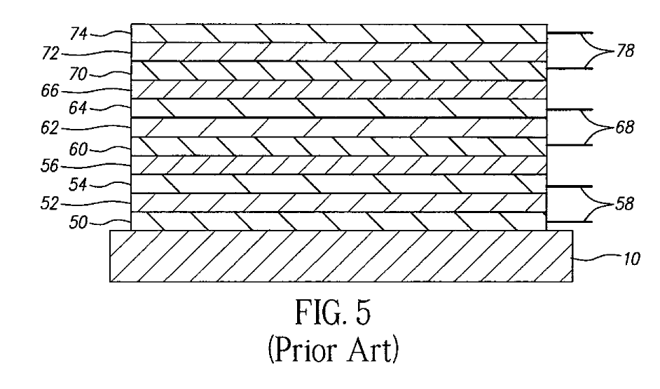

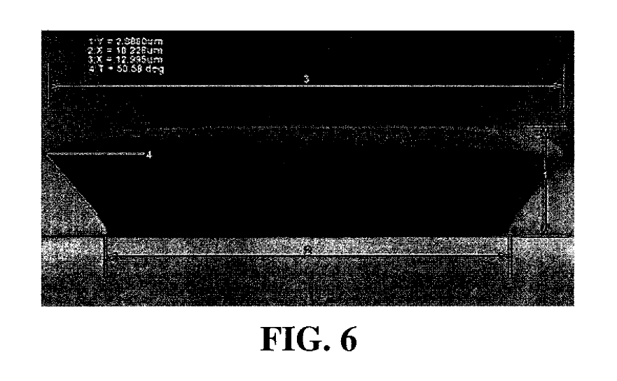

Referring to FIG. 4A, a partially constructed cross section of one embodiment of the present invention is shown having a substrate 10, thin-film electrical components 30, a planarization and insulating layer 32, and pillars 11 corresponding to steps 100 and 102 of FIG. 3. Referring to FIG. 4B, the first patterned electrode 12 (formed in step 110) and the first light-emitting layer 14 (formed in step 115) are illustrated. Referring to FIG. 4C, the second patterned electrode 16 (formed in step 120), the second light-emitting layer 18 (formed in step 125), and the third electrode 20 (formed in step 130) are illustrated. Referring to FIG. 6, a shadowing pillar made by applicant and useful for various embodiments of the present invention is shown.

In the prior art, transparent electrodes are formed of transparent, conductive metal oxides, for example indium tin oxide (ITO). This material is typically deposited by sputtering and is patterned either through photolithographic means or with shadow masks. While photolithographic processes may be suitable for the first patterned electrode, such processes are very problematic in the presence of light-emitting layers, for example organic layers, such as the first light-emitting layer because they will damage the light-emitting layers.

Hence, in a preferred embodiment of the method of the present invention, the second, patterned electrode 16 is formed through deposition over the first light-emitting layer 14 without the use of shadow masks or photolithographic processes. The shadowing pillars 11 at each side of the light-emitting areas are formed such that the top portion of the pillar 11 is wider than the bottom portion. Therefore, any deposition process, such as sputtering, that relies upon a directional deposition will not form material in the undercut areas at the bottom of the shadowing pillars 11. As shown in FIG. 10, the first and second patterned electrodes form a plurality of distinct and separate light-emitting areas 40, 42 separated by a grid of shadowing pillars. The grid may be continuous and effectively form a plurality of wells with shadowing walls. The grid may have rectangular openings corresponding to the light-emitting areas; alternatively, other shapes may be employed. When the material for the second electrode 16 is deposited (as shown in FIG. 4C), it may also deposit over a via formed through the first light-emitting layer(s), thereby connecting the second patterned electrode 16 to an underlying bus or thin-film electrical circuit 30.

After the second electrode 16 is deposited, the second light-emitting layer(s) 18 may be deposited in a fashion similar to that of the first light-emitting layer 14. Over the second light-emitting layer(s) 18, the third electrode 20 is deposited. While the third electrode 20 may be formed in a patterned arrangement like the second electrode 16, it is difficult to form vias through the second electrode 16. Laser ablation is much more difficult to perform through transparent metal oxides than through organic materials and photolithographic processes may very well destroy the second (and first) light-emitting layer(s) 14 and 18. Hence, the third electrode 20 may be a common electrode that is electrically connected to all of the light emitting areas. To construct such a common electrode, the shadowing pillars may be of a height slightly greater than the height of the layers beneath the second light-emitting layer(s) 18 (to enable shadowed deposition of the electrodes 12 and 16) but not much greater, so that the deposition of the third electrode 20 can be continuous over the tops of the shadowing pillars 11 without causing any breaks in the third electrode 20. The third electrode may be thicker than the second electrode to help maintain the continuity of the third electrode 20. In a bottom emitter configuration, a very thick layer of reflective metal (e.g. 400 nm or more) may be employed. In a top-emitter configuration a transparent conductor such as ITO may be employed.

Because the third electrode 20 is common to all of the light-emitting areas, the second patterned electrode 16 must provide current to both the first and second light emitting layers 14 and 18 and the second electrode 16 is therefore shared between the first and second light-emitting layers 14 and 18.

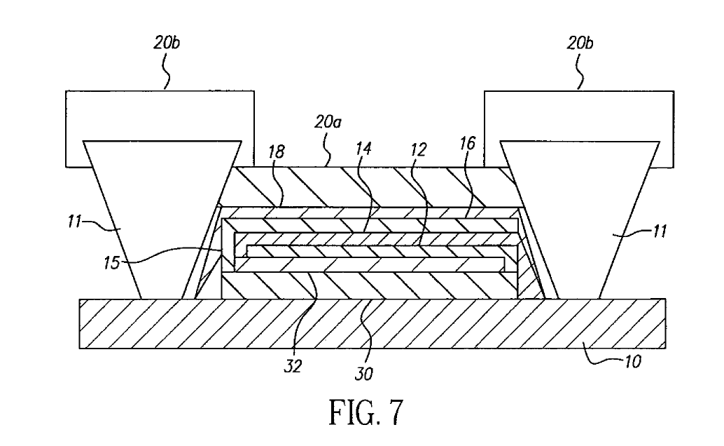

Referring to FIG. 7, the third electrode 20 may comprise multiple layers. It may be desirable, for example, that the portion of the third electrode 20 over the light-emitting area be as thin as possible to provide the maximum transparency. Hence, an initial deposition of a transparent conductor component 20a (for example, ITO) may be made that may or may not (as shown) extend over the shadowing pillars 11. In this case, a second component 20b of third common electrode 20 may be employed over the shadowing pillars 11 to provide additional conductivity and electrical connectivity (if needed). The second component 20b need not be transparent and can comprise, for example, metal bus lines (for example silver or aluminum or compounds including silver and aluminum) or bus lines made of sintered silver nano-particles as described, for example, in U.S. Pat. No. 6,812,637, issued Nov. 2, 2004, entitled “OLED Display With Auxiliary Electrode” by Cok et al, US Publication No. 2006/0057502, filed Apr. 12, 2005, by Okada et al., US Publication No. 2006/0073667, filed Oct. 5, 2004, by Li et al., and US Publication No. 2006/0003262, filed Jun. 30, 2004, by Yang et al., and are hereby incorporated by reference in their entirety.

Thin-film electronic components in circuit 30 can be formed using known lithographic techniques. The deposition of metal and metal oxide layers using techniques such as sputtering and evaporation are also known, as is the use of shadow masks for patterning. The evaporation of organic materials with and without masks are likewise known in the art. Shadowing pillars may be formed using photo-resistive materials and etchants. The performance of the present invention may be improved by employing light scattering techniques as described in, for example, co-pending, commonly assigned U.S. Ser. No. 11/065,082, filed Feb. 24, 2005 entitled “OLED Device Having Improved Light Output” by Cok which is hereby incorporated in its entirety by reference.

FIG. 9 illustrates an equivalent electrical circuit for an embodiment of the present invention. Referring, to FIG. 9, the organic light-emitting diode layer(s) 14 and 18 are shown connected through first and second electrodes 12 and 16 to a control circuit 30 for supplying current. Third electrode 20 is connected in common to the light-emitting layer(s) 18 of the plurality of OLEDs defined by the light-emitting areas. The third electrode 20 may be connected to the electronic circuit 30 or may be connected externally to a controller that also supplies signals and power to the electronic circuit 30.

The device of the present invention may be operated in either of at least two modes. In a first mode, light emission from the first light-emitting layer 14 and the second light-emitting layer 18 is temporally alternated so that first one layer is energized to produce light and then the second layer is energized to produce light. In this mode, both layers do not emit at the same time. However, the temporal alternation must be done at a sufficiently high frequency that viewers do not observe a flickering effect. In a second mode, both layers are operated simultaneously or independently. In the first mode, to operate the first light-emitting layer 14 while turning off the second light-emitting layer 18, the electrodes 16 and 20 may be held at the same potential while controlling the current through the first light-emitting layer 14 via electrodes 12 and 16. This can be accomplished since both electrodes 12 and 16 may be connected to thin-film electronic circuit 30. To operate the second light-emitting layer 18 while turning off the first light-emitting layer 14, the electrodes 12 and 16 may be held at the same potential while controlling the current through the second light-emitting layer 18 via electrode 16. This can be accomplished since electrode 16 may be connected to thin-film electronic circuit 30.

In the second mode, the first light-emitting layer 14 and the second light-emitting layer 18 are operated simultaneously so that both light-emitting layers are energized and produce light at the same time. In this mode, the three electrodes must be held at relatively controlled potential levels. Current passing through the first light-emitting layer 14 is controlled by the potential between first and second electrodes 12 and 16 while current passing through the second light-emitting layer 18 is controlled by the potential between second and third electrodes 16 and 20. Hence, to provide equal current through both light-emitting layers 14 and 18, for example, the potential difference between first and second electrodes 12 and 16 is held to the same potential difference as between electrodes 16 and 20. Since only one electrode is common (electrode 20), the first and second electrodes 12 and 16 may be controlled by the thin-film electronic circuit 30 to achieve the desired potential differences.

In accordance with other embodiments of the present invention, the order of the organic layers within the light-emitting layers 14 or 18 may be inverted with respect to each other, thereby changing the direction of current flow through the light-emitting layers and the electronic circuit controlling the current flow. Alternatively, the order may not be inverted.

OLED devices of this invention can employ various well-known optical effects in order to enhance their properties if desired. This includes optimizing layer thicknesses to yield maximum light transmission, providing anti-glare or anti-reflection coatings over the display, or providing colored, neutral density, or color conversion filters over the display. Filters, and anti-glare or anti-reflection coatings may be specifically provided over the cover or as part of the cover.

The present invention may also be practiced with either active- or passive-matrix OLED devices. It may also be employed in display devices or in area illumination devices. In a preferred embodiment, the present invention is employed in a flat-panel OLED device composed of small molecule or polymeric OLEDs as disclosed in but not limited to U.S. Pat. No. 4,769,292, issued Sep. 6, 1988 to Tang et al., and U.S. Pat. No. 5,061,569, issued Oct. 29, 1991 to VanSlyke et al. Many combinations and variations of organic light-emitting displays can be used to fabricate such a device, including both active- and passive-matrix OLED displays having either a top- or bottom-emitter architecture.

The invention has been described in detail with particular reference to certain preferred embodiments thereof, but it will be understood that variations and modifications can be effected within the spirit and scope of the invention.

### PARTS LIST

10 substrate
11 shadowing pillars
12 patterned electrode
14 first light-emitting layers
16 patterned shared electrode
18 second light-emitting layers
20 third common electrode
20a third common electrode transparent component
20b third common electrode component
22 color filter
30 thin-film electronic circuit
32 planarizing insulator
40 first light-emitting area
42 second light-emitting area
50 electrode
52 light-emitting layer
54 electrode
56 insulating layer
58 power connections
60 electrode
62 light-emitting layer
64 electrode
66 insulating layer
68 power connections
70 electrode
72 light-emitting layer
74 electrode
78 power connections
100 provide substrate step
102 for thin-film electronic components step
105 form pillars step
110 form first electrode step
115 form first light-emitting layer(s) step
117 form via step
120 form second electrode step
125 form second light-emitting layer(s) step
130 form third electrode step

1. An organic light-emitting diode device, comprising:
a) a substrate having a plurality of first and second electrical conductors and a two-dimensional continuous grid of shadowing pillars formed over the substrate;
b) a plurality of first patterned, electrically isolated electrodes formed over the substrate and connected to corresponding first electrical conductors;
c) one-or-more organic first light-emitting layer(s) formed over the first patterned electrodes;
d) a plurality of second patterned, electrically isolated electrodes formed between the shadowing pillars over the first patterned electrodes and the one-or-more first light-emitting layer(s) electrically connected to corresponding second patterned electrical conductors through vias formed in the first light-emitting layer(s) between the shadowing pillars, the first and second patterned electrodes defining a corresponding plurality of light-emitting areas separated by the grid of shadowing pillars;
e) one or more organic second light-emitting layer(s) formed over the second patterned electrodes;
f) a third electrode electrically common to the plurality of light-emitting areas formed over the one-or-more second light-emitting layer(s), the shadowing pillars, and the plurality of light-emitting areas; and
g) wherein each of the second patterned electrodes is shared between the first and second light-emitting layers, within each of the plurality of light-emitting areas, so that the first and second patterned electrodes provide current through the first light-emitting layer(s); and each of the second and third electrodes, within each of the plurality of light-emitting areas, provide current through the second light-emitting layer(s) independent of the current through the first light-emitting layer.

2. The organic light-emitting diode device of claim 1, wherein each of the first and second patterned electrodes is transparent and the third electrode is reflective.

3. The organic light-emitting diode device of claim 1, wherein each of the first patterned electrodes is reflective and each of the second patterned electrode and the third electrode are transparent.

4.-6. (canceled)

7. The organic light-emitting diode device of claim 1, further comprising an electronic circuit connected to the first patterned electrode and to the second patterned electrode.

8. The organic light-emitting diode device of claim 1, wherein light emitted from the first and second one-or-more light-emitting layers is independently controllable to emit light from either the first or second light-emitting layer or to emit light from both the first and second light-emitting layers in combination with each other.

9. The organic light-emitting diode device of claim 1, wherein the first light-emitting layer(s) emit the same first color of light in each of the plurality of light-emitting areas and the second light-emitting layer(s) emit the same second color of light in each of the plurality of light-emitting areas and wherein the first and second colors are different colors.

10. The organic light-emitting diode device of claim 9, wherein:
a) one of the first or second light-emitting layer(s) emits green light and the other of the first or second light-emitting layers emits magenta light; or
b) one of the first or second light-emitting layer(s) emits blue light and the other of the first or second light-emitting layers emits yellow light; or
c) one of the first or second light-emitting layer(s) emits red light and the other of the first or second light-emitting layers emits cyan light; or
d) one of the first or second light-emitting layer(s) emits cyan light and the other of the first or second light-emitting layers emits yellow light; or
e) one of the first or second light-emitting layer(s) emits cyan light and the other of the first or second light-emitting layers emits magenta light; or
f) one of the first or second light-emitting layer(s) emits yellow light and the other of the first or second light-emitting layers emits magenta light

11. The organic light-emitting diode device of claim 1, wherein one of the first and second light-emitting layer(s) emits light of different colors in different light-emitting areas and the other of the first and second light-emitting layer(s) emits light of the same color in all light-emitting areas.

12. The organic light-emitting diode device of claim 11 wherein the different colors are red and blue and the same color is green.

13. The organic light-emitting diode device of claim 1, wherein both of the first and second light-emitting layer(s) emits light of different colors in different light-emitting areas.

14. The organic light-emitting diode device of claim 1, further comprising a color filter for filtering the light output from the first and second light-emitting layer(s).

15. The organic light-emitting diode device of claim 14, wherein at least one of the color filters are yellow, cyan, or magenta.

16. The organic light-emitting diode device of claim 14 wherein different color filters are used with different light-emitting areas.

17. A method for making an organic light-emitting diode device, comprising the steps of:
a) forming a plurality of first patterned electrodes that define a plurality of first light-emitting areas on a substrate;
b) forming one-or-more organic first light-emitting layer(s) over the first patterned electrodes;
c) forming a plurality of second patterned electrodes over the one-or-more first light-emitting layer(s) that define a plurality of second light-emitting areas;
d) forming one or more organic second light-emitting layer(s) over the second patterned shared electrodes;
e) forming a third electrode common to the second light-emitting areas over the one-or-more second light-emitting layer(s);
f) wherein each of the second patterned electrodes is shared between the first and second light-emitting layers, within each of the first light-emitting areas, so that the first and second patterned electrodes provide current through the first light-emitting layer(s); and each of the second and third patterned electrodes, within each of the second light-emitting areas, provide current through the second light-emitting layer(s) independent of the current through the first light-emitting layer.

18. The method of claim 17 further comprising the steps of forming thin-film electronic components over the substrate, wherein the first patterned electrodes are electrically connected to the thin-film electronic components; and forming a via through the one-or-more first light-emitting layer(s) to electrically connect the second patterned shared electrode to the thin-film electronic components when the second patterned shared electrode is formed.

19. The method of claim 18 wherein the via is formed by laser ablation of the first light-emitting layers.

20. A method for making an organic light-emitting diode device, comprising the steps of:
a) providing a substrate;
b) forming electrically insulating shadowing pillars on the substrate;
c) forming a plurality of first patterned electrodes that define a plurality of first light-emitting areas over the substrate;
d) forming one-or-more organic first light-emitting layer(s) over the first patterned electrodes;
e) forming a plurality of second patterned electrodes over the one-or-more first light-emitting layer(s) that define a plurality of second light-emitting areas between the shadowing pillars;
f) forming one or more organic second light-emitting layer(s) over the second patterned shared electrodes;
g) forming a third electrode common to the second light-emitting areas over the one-or-more second light-emitting layer(s) and over the shadowing pillars; and
h) wherein each of the second patterned electrodes is shared between the first and second light-emitting layers, within each of the first light-emitting areas, so that the first and second patterned electrodes provide current through the first light-emitting layer(s); and each of the second and third patterned electrodes, within each of the second light-emitting areas, provide current through the second light-emitting layer(s) independent of the current through the first light-emitting layer.
